(19) United States
(12) Patent Application Publication
(10) Pub. No.: US 2023/0418351 A1
(43) Pub. Date: Dec. 28, 2023

(54) SYSTEMS AND METHODS FOR DEPASSIVATION OF A BATTERY OF AN INTERNET-OF-THINGS DEVICE

(71) Applicant: Positioning Universal Inc., San Diego, CA (US)

(72) Inventors: Jorma Seppanen, San Diego, CA (US); Mark Wells, San Diego, CA (US); Greg Sutton, San Diego, CA (US)

(21) Appl. No.: 18/339,469

(22) Filed: Jun. 22, 2023

Related U.S. Application Data
(60) Provisional application No. 63/354,483, filed on Jun. 22, 2022.

(51) Int. Cl. G06F 1/30; H02J 13/00; H01M 10/48; H01M 10/42; G16Y 20/30; G16Y 40/40; G01R 31/385; G01R 31/392

(52) U.S. Cl. CPC G06F 1/30; H02J 13/00002; H02J 13/00028; H01M 10/48; H01M 10/425; G16Y 20/30; G16Y 40/40; G01R 31/386; G01R 31/392; H01M 2010/4271

(57) ABSTRACT

Embodiments of the present disclosure provide systems and methods for extending the operational life of battery-operated devices, such as an Internet-of-Things device, by adapting the device to monitor its' own battery condition, and in response to detecting conditions indicating passivation of the battery, execute a refresh cycle to restore battery capacity. In this way, the battery can be refreshed by running a series of oxidation ‘burn off’ cycles periodically during the device's lifetime.

### CROSS REFERENCE TO RELATED APPLICATIONS

The present application claims the benefits of and priority, under 35 U.S.C. § 119(e), to U.S. Provisional Application No. 63/354,483, filed Jun. 22, 2022, entitled “SYSTEMS AND METHODS FOR DEPASSIVATION OF A BATTERY OF AN INTERNET-OF-THINGS DEVICE” of which the entire disclosure of which is incorporated by reference for all purposes.

### FIELD OF THE DISCLOSURE

Embodiments of the present disclosure relate generally to methods and systems for powering an Internet of Things (IoT) device and more particularly to maintaining a battery power supply of an IoT device.

### BACKGROUND

Internet-of-Things (IoT) devices are compact, wireless devices with sensors, processing ability, software, and other technologies that connect and exchange data with other devices and systems over the Internet or other communications networks. Such devices typically, collect data and transmit, perhaps periodically, this data to a server or other, remote computing device. Many IoT devices are expected to operate on battery power in use for many years with extremely low power consumption. Because the device power consumption is very minimal and depending on the battery chemistry, the expected battery capacity can deteriorate faster than expected due to oxidation which happens inside battery cells. This oxidation and the resulting deterioration is commonly known as passivation. Excessive passivation can result in the battery being unusable. Hence, there is a need in the art for methods and systems for preventing passivation in IoT devices.

### BRIEF SUMMARY

Embodiments of the disclosure provide systems and methods for managing a battery power supply in an Internet-of-Things (IoT) device. According to one embodiment, a method for maintaining a battery in an IoT device can comprise determining, by a processor of the IoT device, whether to perform battery maintenance. Determining to perform battery maintenance can comprise determining whether a predefined period of time has passed. Additionally, or alternatively, determining to perform battery maintenance can comprise receiving, from a remote monitoring system, an instruction to perform battery maintenance. In response to determining to perform battery maintenance, a pre-check process can be performed, by the processor of the IoT device, on the battery of the IoT device. A determination can be made, by the processor of the IoT device, based on results of performing the pre-check process, as to whether battery passivation is occurring on the battery of the IoT device. In response to determining battery passivation is occurring on the IoT device, a de-passivation process can be performed, by the processor of the IoT device, on the battery of the IoT device. In some cases, results of at least one of the pre-check process or the de-passivation process can be provided, by the processor of the IoT device, to a remote monitoring system. Additionally, or alternatively, updated parameters for at least one of the pre-check process or the de-passivation process can be received, by the processor of the IoT device, from the remote monitoring system.

Performing the pre-check process on the battery of the IoT device can comprise initiating a burn-off process on the battery by applying a known load to the battery for a predetermined period of time, detecting a voltage drop on the battery during the burn-off process, and determining whether the voltage drop on the battery during the burn-off process remains within a set of predefined limits. In response to determining the voltage drop of the battery during the burn-off process does not remain within the set of predefined limits, a result indicating that battery passivation is occurring on the battery can be provided.

Performing the de-passivation process can comprise performing a burn-off process on the battery by applying a known load to the battery, measuring battery voltage during the burn-off process, and determining whether the battery voltage remains greater than a predefined target voltage for a predefined period of time. In response to determining the battery voltage remains greater than the predefined target voltage for the predefined period of time for the burn-off process, the de-passivation process can be ended. In response to determining the battery voltage does not remain greater than the predefined target voltage for the predefined period of time for the burn-off process, a further determination can be made as to whether a pre-determined maximum number of de-passivation cycles have been performed. In response to determining the pre-determined maximum number of de-passivation cycles have been performed, the de-passivation process can be ended.

In response to determining the battery voltage does not remain greater than the predefined target voltage for the predefined period of time for the burn-off process and in response to determining the pre-determined maximum number of de-passivation cycles have not yet been performed, the burn-off process on the battery can be paused for a predetermined period of time. After the predetermined period of time for pausing the burn-off process on the battery has expired, the performing of the burn-off process on the battery and the measuring of the battery voltage during the burn-off process can be repeated until a determination is made that the battery voltage remains greater than the predefined target voltage for the predefined period of time for the burn-off process or until a determination is made that the pre-determined maximum number of de-passivation cycles have been performed.

According to another embodiment, an Internet-of-Things (IoT) device can comprise a processor and a memory coupled with and readable by the processor. The processor can store therein a set of instructions which, when executed by the processor, causes the processor to determine whether to perform battery maintenance. Determining to perform battery maintenance can comprise determining whether a predefined period of time has passed. Additionally, or alternatively, determining to perform battery maintenance can comprise receiving, from a remote monitoring system, an instruction to perform battery maintenance.

In response to determining to perform battery maintenance, the instructions can cause the processor to perform a pre-check process on the battery of the IoT device. Performing the pre-check process on the battery of the IoT device can comprise initiating a burn-off process on the battery by applying a known load to the battery for a predetermined period of time, detecting a voltage drop on the battery during the burn-off process, and determining whether the voltage drop on the battery during the burn-off process remains within a set of predefined limits. In response to determining the voltage drop of the battery during the burn-off process does not remain within the set of predefined limits, a result indicating that battery passivation is occurring on the battery can be provided.

The instructions can further cause the processor to make a determination can be made based on results of performing the pre-check process, as to whether battery passivation is occurring on the battery of the IoT device. In response to determining battery passivation is occurring on the IoT device, a de-passivation process can be performed, by the processor of the IoT device, on the battery of the IoT device. Performing the de-passivation process can comprise performing a burn-off process on the battery by applying a known load to the battery, measuring battery voltage during the burn-off process, and determining whether the battery voltage remains greater than a predefined target voltage for a predefined period of time. In response to determining the battery voltage remains greater than the predefined target voltage for the predefined period of time for the burn-off process, the de-passivation process can be ended. In response to determining the battery voltage does not remain greater than the predefined target voltage for the predefined period of time for the burn-off process, a further determination can be made as to whether a pre-determined maximum number of de-passivation cycles have been performed. In response to determining the pre-determined maximum number of de-passivation cycles have been performed, the de-passivation process can be ended.

In response to determining the battery voltage does not remain greater than the predefined target voltage for the predefined period of time for the burn-off process and in response to determining the pre-determined maximum number of de-passivation cycles have not yet been performed, the burn-off process on the battery can be paused for a predetermined period of time. After the predetermined period of time for pausing the burn-off process on the battery has expired, the performing of the burn-off process on the battery and the measuring of the battery voltage during the burn-off process can be repeated until a determination is made that the battery voltage remains greater than the predefined target voltage for the predefined period of time for the burn-off process or until a determination is made that the pre-determined maximum number of de-passivation cycles have been performed.

In some cases, the instructions can further cause the processor to provide results of at least one of the pre-check process or the de-passivation process to a remote monitoring system. Additionally, or alternatively, the instructions can further cause the processor to receive updated parameters for at least one of the pre-check process or the de-passivation process from the remote monitoring system.

### BRIEF DESCRIPTION OF THE DRAWINGS

FIG. 1 is a block diagram illustrating elements of an exemplary environment in which embodiments of the present disclosure may be implemented.

FIG. 2 is a block diagram illustrating elements of an Internet of Things (IoT) device in which embodiments of the present disclosure may be implemented.

FIG. 3 is a flowchart illustrating an exemplary process for maintaining a battery of an IoT device according to one embodiment of the present disclosure.

FIG. 4 is a flowchart illustrating additional details of an exemplary pre-check process according to one embodiment of the present disclosure.

FIG. 5 is a flowchart illustrating additional details of an exemplary de-passivation process according to one embodiment of the present disclosure.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the second reference label.

### DETAILED DESCRIPTION

In the following description, for the purposes of explanation, numerous specific details are set forth in order to provide a thorough understanding of various embodiments disclosed herein. It will be apparent, however, to one skilled in the art that various embodiments of the present disclosure may be practiced without some of these specific details. The ensuing description provides exemplary embodiments only and is not intended to limit the scope or applicability of the disclosure. Furthermore, to avoid unnecessarily obscuring the present disclosure, the preceding description omits a number of known structures and devices. This omission is not to be construed as a limitation of the scopes of the claims. Rather, the ensuing description of the exemplary embodiments will provide those skilled in the art with an enabling description for implementing an exemplary embodiment. It should however be appreciated that the present disclosure may be practiced in a variety of ways beyond the specific detail set forth herein.

While the exemplary aspects, embodiments, and/or configurations illustrated herein show the various components of the system collocated, certain components of the system can be located remotely, at distant portions of a distributed network, such as a Local-Area Network (LAN) and/or Wide-Area Network (WAN) such as the Internet, or within a dedicated system. Thus, it should be appreciated, that the components of the system can be combined in to one or more devices or collocated on a particular node of a distributed network, such as an analog and/or digital telecommunications network, a packet-switch network, or a circuit-switched network. It will be appreciated from the following description, and for reasons of computational efficiency, that the components of the system can be arranged at any location within a distributed network of components without affecting the operation of the system.

Furthermore, it should be appreciated that the various links connecting the elements can be wired or wireless links, or any combination thereof, or any other known or later developed element(s) that is capable of supplying and/or communicating data to and from the connected elements. These wired or wireless links can also be secure links and may be capable of communicating encrypted information. Transmission media used as links, for example, can be any suitable carrier for electrical signals, including coaxial cables, copper wire and fiber optics, and may take the form of acoustic or light waves, such as those generated during radio-wave and infra-red data communications.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted that the terms “comprising,” “including,” and “having” can be used interchangeably.

The term “automatic” and variations thereof, as used herein, refers to any process or operation done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

The term “computer-readable medium” as used herein refers to any tangible storage and/or transmission medium that participate in providing instructions to a processor for execution. Such a medium may take many forms, including but not limited to, non-volatile media, volatile media, and transmission media. Non-volatile media includes, for example, Non-Volatile Random-Access Memory (NVRAM), or magnetic or optical disks. Volatile media includes dynamic memory, such as main memory. Common forms of computer-readable media include, for example, a floppy disk, a flexible disk, hard disk, magnetic tape, or any other magnetic medium, magneto-optical medium, a Compact Disk Read-Only Memory (CD-ROM), any other optical medium, punch cards, paper tape, any other physical medium with patterns of holes, a Random-Access Memory (RAM), a Programmable Read-Only Memory (PROM), and Erasable Programmable Read-Only Memory (EPROM), a Flash-EPROM, a solid state medium like a memory card, any other memory chip or cartridge, a carrier wave as described hereinafter, or any other medium from which a computer can read. A digital file attachment to e-mail or other self-contained information archive or set of archives is considered a distribution medium equivalent to a tangible storage medium. When the computer-readable media is configured as a database, it is to be understood that the database may be any type of database, such as relational, hierarchical, object-oriented, and/or the like. Accordingly, the disclosure is considered to include a tangible storage medium or distribution medium and prior art-recognized equivalents and successor media, in which the software implementations of the present disclosure are stored.

A “computer readable signal” medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable medium may be transmitted using any appropriate medium, including but not limited to wireless, wireline, optical fiber cable, Radio Frequency (RF), etc., or any suitable combination of the foregoing.

The terms “determine,” “calculate,” and “compute,” and variations thereof, as used herein, are used interchangeably and include any type of methodology, process, mathematical operation or technique.

It shall be understood that the term “means” as used herein shall be given its broadest possible interpretation in accordance with 35 U.S.C., Section 112, Paragraph 6. Accordingly, a claim incorporating the term “means” shall cover all structures, materials, or acts set forth herein, and all of the equivalents thereof. Further, the structures, materials or acts and the equivalents thereof shall include all those described in the summary of the disclosure, brief description of the drawings, detailed description, abstract, and claims themselves.

Aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Any combination of one or more computer readable medium(s) may be utilized. The computer readable medium may be a computer readable signal medium or a computer readable storage medium.

In yet another embodiment, the systems and methods of this disclosure can be implemented in conjunction with a special purpose computer, a programmed microprocessor or microcontroller and peripheral integrated circuit element(s), an ASIC or other integrated circuit, a digital signal processor, a hard-wired electronic or logic circuit such as discrete element circuit, a programmable logic device or gate array such as Programmable Logic Device (PLD), Programmable Logic Array (PLA), Field Programmable Gate Array (FPGA), Programmable Array Logic (PAL), special purpose computer, any comparable means, or the like. In general, any device(s) or means capable of implementing the methodology illustrated herein can be used to implement the various aspects of this disclosure. Exemplary hardware that can be used for the disclosed embodiments, configurations, and aspects includes computers, handheld devices, telephones (e.g., cellular, Internet enabled, digital, analog, hybrids, and others), and other hardware known in the art. Some of these devices include processors (e.g., a single or multiple microprocessors), memory, nonvolatile storage, input devices, and output devices. Furthermore, alternative software implementations including, but not limited to, distributed processing or component/object distributed processing, parallel processing, or virtual machine processing can also be constructed to implement the methods described herein.

Examples of the processors as described herein may include, but are not limited to, at least one of Qualcomm® Snapdragon® 800 and 801, Qualcomm® Snapdragon® 610 and 615 with 4G LTE Integration and 64-bit computing, Apple® A7 processor with 64-bit architecture, Apple® M7 motion coprocessors, Samsung® Exynos® series, the Intel® Core™ family of processors, the Intel® Xeon® family of processors, the Intel® Atom™ family of processors, the Intel Itanium® family of processors, Intel® Core® i5-4670K and i7-4770K 22 nm Haswell, Intel® Core® i5-3570K 22 nm Ivy Bridge, the AMD® FX™ family of processors, AMD® FX-4300, FX-6300, and FX-8350 32 nm Vishera, AMD® Kaveri processors, Texas Instruments® Jacinto C6000™ automotive infotainment processors, Texas Instruments® OMAP™ automotive-grade mobile processors, ARM® Cortex™-M processors, ARM® Cortex-A and ARM926EJ-S™ processors, other industry-equivalent processors, and may perform computational functions using any known or future-developed standard, instruction set, libraries, and/or architecture.

In yet another embodiment, the disclosed methods may be readily implemented in conjunction with software using object or object-oriented software development environments that provide portable source code that can be used on a variety of computer or workstation platforms. Alternatively, the disclosed system may be implemented partially or fully in hardware using standard logic circuits or Very Large-Scale Integration (VLSI) design. Whether software or hardware is used to implement the systems in accordance with this disclosure is dependent on the speed and/or efficiency requirements of the system, the particular function, and the particular software or hardware systems or microprocessor or microcomputer systems being utilized.

In yet another embodiment, the disclosed methods may be partially implemented in software that can be stored on a storage medium, executed on programmed general-purpose computer with the cooperation of a controller and memory, a special purpose computer, a microprocessor, or the like. In these instances, the systems and methods of this disclosure can be implemented as program embedded on personal computer such as an applet, JAVA® or Common Gateway Interface (CGI) script, as a resource residing on a server or computer workstation, as a routine embedded in a dedicated measurement system, system component, or the like. The system can also be implemented by physically incorporating the system and/or method into a software and/or hardware system.

Although the present disclosure describes components and functions implemented in the aspects, embodiments, and/or configurations with reference to particular standards and protocols, the aspects, embodiments, and/or configurations are not limited to such standards and protocols. Other similar standards and protocols not mentioned herein are in existence and are considered to be included in the present disclosure. Moreover, the standards and protocols mentioned herein and other similar standards and protocols not mentioned herein are periodically superseded by faster or more effective equivalents having essentially the same functions. Such replacement standards and protocols having the same functions are considered equivalents included in the present disclosure.

Various additional details of embodiments of the present disclosure will be described below with reference to the figures. While the flowcharts will be discussed and illustrated in relation to a particular sequence of events, it should be appreciated that changes, additions, and omissions to this sequence can occur without materially affecting the operation of the disclosed embodiments, configuration, and aspects.

Embodiments of the present disclosure provide systems and methods for extending the operational life of battery-operated devices, such as an Internet-of-Things device, by adapting the device to monitor its' own battery condition, and in response to detecting conditions indicating passivation of the battery, execute a refresh cycle to restore battery capacity. In this way, the battery can be refreshed by running a series of oxidation ‘burn off’ cycles periodically during the device's lifetime.

In the following examples, embodiments of the present disclosure are described in the context of an IOT vehicle monitoring device. However, it should be understood that these examples are provided for illustrative purposes only and are not intended to limit the scope of the present disclosure. Rather, embodiments described herein are thought to be equally applicable to other types of IoT or even other types of devices in which efficient and effective battery management is important. Implementation in such devices is considered to be within the scope of the present disclosure.

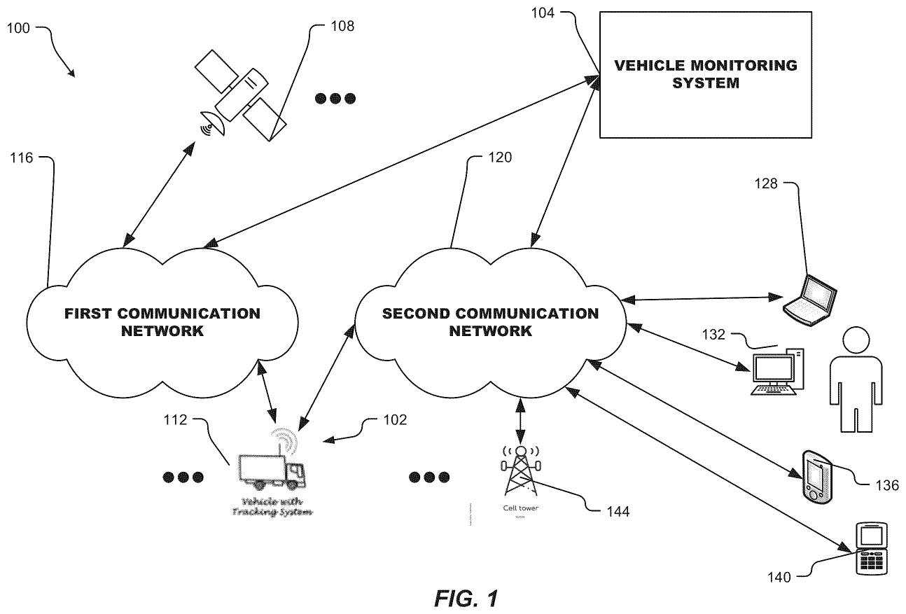

FIG. 1 is a block diagram illustrating elements of an exemplary environment in which embodiments of the present disclosure may be implemented. More specifically, this example illustrates a vehicle monitoring architecture 100, comprising an IoT vehicle monitoring device 102 on a monitored vehicle 112 (shown as a truck), in communication with a satellite navigation system 108 via a first communication network 116 and with a vehicle monitoring system 104 via a second communication network 120, is shown in accordance with embodiments of the present disclosure. The monitored vehicle 112 can be any vehicle, aircraft, ship, trailer, storage container or other cargo, shipment, electronic device such as a smart phone, or other asset. As shown, multiple monitored vehicles 112 can be monitored simultaneously. The vehicle monitoring system 104, in turn, is in communication with the satellite navigation system 108, via the first communication network 116, and one or more computational devices, such as a laptop 128, personal computer 132, personal digital assistant 136 (e.g., a tablet computer), and/or a smart phone 140, of a user 124 via the second communication network 120. The satellite navigation system 108 can be any global or regional satnav system and typically includes not only satellites but also ground stations to monitor and control satellites and receivers to listen for signals from the satellites. The first communication network 116 can be a radio network configured to operate with the satellite navigation system 108 to provide radionavigation-satellite service.

The second communication network 120 may comprise any type of known communication medium or collection of communication media and may use any type of protocols to transport messages between endpoints. The second communication network 120 may include wired and/or wireless communication technologies (as shown by plural base stations 144). The Internet is an example of the second communication network 120 that constitutes an Internet Protocol (“IP”) network comprising computers, computing networks, and other communication devices located all over the world, which are connected through many telephone systems and other means. Other examples of the second communication network 120 include, without limitation, a standard Plain Old Telephone System (“POTS”), an Integrated Services Digital Network (“ISDN”), the Public Switched Telephone Network (“PSTN”), a Local Area Network (“LAN”), a Wide Area Network (“WAN”), a VoIP network, a Session Initiation Protocol (“SIP”) network, a cellular network, and any other type of packet-switched or circuit-switched network known in the art. In addition, it can be appreciated that the second communication network 120 need not be limited to any one network type, and instead may be comprised of a number of different networks and/or network types. The second communication network 120 may comprise a number of different communication media such as coaxial cable, copper cable/wire, fiber-optic cable, antennas for transmitting/receiving wireless messages, and combinations thereof.

Generally speaking, the IoT vehicle monitoring device 102 can collect information regarding operation and/or location of the monitored vehicle 112. This information can include, but is not limited to location information obtained through the first communication network 116 as well as operating parameters of the vehicle. This collected information can be provided by the IoT vehicle monitoring device 102 to the vehicle monitoring system 104 via the second communication network 120. The vehicle monitoring system 104 can in turn make the information available to users of various devices 128, 132, 136, and 140 through the second communication network 120. As will be described below, the IoT vehicle monitoring device 102 can maintain the collected data in memory of the IoT vehicle monitoring device 102 according to embodiments of the present disclosure.

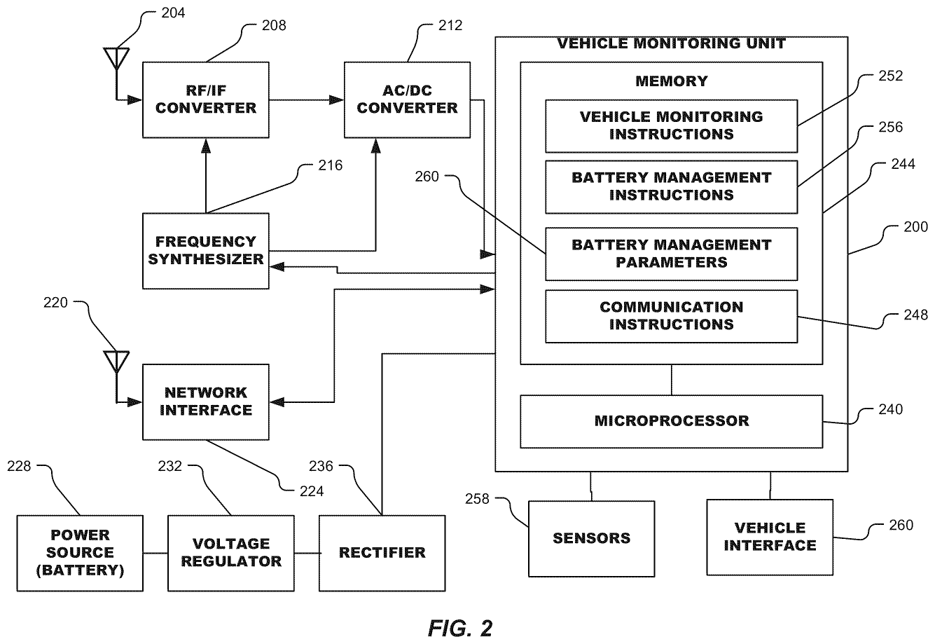

FIG. 2 is a block diagram illustrating elements of an IoT device in which embodiments of the present disclosure may be implemented. More specifically, and as illustrated in this example, the IoT vehicle monitoring device 102 is shown to include a vehicle monitoring unit 200 engaged with a first antenna 204 (such as an RF antenna) to receive signals from and send signals to the satellite navigation system 108 via the first communication network 116 in communication with an RF/IF converter 208, AC/DC converter 212 and frequency synthesizer 216, a second antenna 220 (such as a WiFi antenna and driver circuit, Bluetooth antenna and driver circuit, or a cellular communication antenna and driver circuit) and network interface 224 to receive signals from and send signals to the vehicle monitoring system 104 via the second communication network 120, and a power source 228, voltage regulator 232, and rectifier 236 to supply electrical energy to the vehicle monitoring unit 200.

The signals transmitted from satellite navigation system 108 are received at the first antenna 204. Through the radio frequency (RF) chain, the input signal is amplified by the RF/IF converter 208 to a selected amplitude, and the frequency is converted by the frequency synthesizer 216 to a desired output frequency. The analogue-to-digital converter (ADC) 212 is used to digitize the amplified and frequency-adjusted input signal.

The configuration of the network interface 224 in signal communication with the second antenna 220 may depend upon the IoT vehicle monitoring device 102. Examples of a suitable network interface 224 include, without limitation, an Ethernet port, a USB port, an RS-232 port, an RS-485 port, a NIC, an antenna, a driver circuit, a modulator/demodulator, etc. The network interface 224 may include one or multiple different network interfaces depending upon whether the IoT vehicle monitoring device 102 is connecting to a single (second) communication network 120 or multiple different types of (second) communication networks 120.

The power source 228 may correspond to an internal power supply that provides AC and/or DC power to components of the IoT vehicle monitoring device 102. In some embodiments, the power source 228 may correspond to one or multiple batteries or capacitors or other electromagnetic energy storage devices. Alternatively, or additionally, the power source 228 may include a power adapter or wireless charger that converts AC power into DC power for direct application to components of the IoT vehicle monitoring device 102, for charging a battery, for charging a capacitor, or a combination thereof.

The vehicle monitoring unit 200, in turn, includes a microprocessor 240 and memory 244. In some embodiments, the microprocessor 240 may correspond to one or many microprocessors, CPUs, microcontrollers, Integrated Circuit (IC) chips, or the like. For instance, the processor 604 may be provided as silicon, as a Field Programmable Gate Array (FPGA), an Application-Specific Integrated Circuit (ASIC), any other type of Integrated Circuit (IC) chip, a collection of IC chips, or the like. As a more specific example, the microprocessor 208 may be provided as a microcontroller, microprocessor, Central Processing Unit (CPU), or plurality of microprocessors that are configured to execute the instructions sets stored in memory 244. The memory 244 may include one or multiple computer memory devices that are volatile or non-volatile. The memory 244 may include volatile and/or non-volatile memory devices. Non-limiting examples of memory 244 include Random Access Memory (RAM), Read Only Memory (ROM), flash memory, Electronically-Erasable Programmable ROM (EEPROM), Dynamic RAM (DRAM), etc. The memory 244, while illustrated here as a single unit, may in various implementation comprise two or more different types of memory. In some cases, these different types of memory may additionally, or alternatively include a flash memory such as a NAND flash, for example, in which data collected by the IoT vehicle monitoring device 102 is stored.

The memory 244 may be configured to store the instruction sets depicted in addition to temporarily storing data for the microprocessor 240 to execute various types of routines or functions. The instruction sets can enable interaction with the IoT vehicle monitoring server 200 and real time tracked object location and state of health monitoring. For example, the memory 244 may store therein a set of vehicle monitoring instructions which, when executed by the microprocessor 240, causes the microprocessor 240 to collect information from the vehicle via one or more sensors 258 installed in or on the vehicle, from the vehicle itself, e.g., though a vehicle interface 260 such as an On-Board Diagnostic (OBD) II or similar interface, etc. The data can comprise one or more parameters related to operation or location of a vehicle in which the IoT vehicle monitoring device is installed. A communication instruction set 248 may enable the vehicle monitoring device 102 to exchange electronic communications, either directly or indirectly, with vehicle monitoring system 104.

The memory 244 can further store therein a set of battery management instructions 256 which, when executed by the processor 240, causes the processor 240 to determine whether to perform maintenance on the battery 228 of the IoT device. Determining to perform battery maintenance can comprise determining whether a predefined period of time has passed, e.g., since a last time battery maintenance was performed or since the batter 228 was installed in the IoT device. Additionally, or alternatively, determining to perform battery maintenance can comprise receiving, from the remote monitoring system 104, an instruction to perform battery maintenance.

In response to determining to perform battery maintenance, the battery management instructions 256 can cause the processor 240 to perform a pre-check process on the battery 228 of the IoT device based on one or more battery management parameters 260. Performing the pre-check process on the battery 228 of the IoT device can comprise initiating a burn-off process on the battery 228 by applying a known load to the battery 228, e.g., powering up the network interface 224 or other component, for a predetermined period of time, detecting a voltage drop on the battery 228 during the burn-off process, and determining whether the voltage drop on the battery 228 during the burn-off process remains within a set of predefined limits. In response to determining the voltage drop of the battery 228 during the burn-off process does not remain within the set of predefined limits, a result indicating that battery passivation is occurring on the battery can be provided.

The battery management instructions 256 can further cause the processor 240 to make a determination can be made based on results of performing the pre-check process, as to whether battery passivation is occurring on the battery 228 of the IoT device. In response to determining battery passivation is occurring on the battery 228 of the IoT device, a de-passivation process can be performed, by the processor 240 of the IoT device, on the battery 228 of the IoT device based on one or more battery management parameters 260. Performing the de-passivation process can comprise performing a burn-off process on the battery 228 by applying a known load to the battery 228, measuring battery voltage during the burn-off process, and determining whether the battery voltage remains greater than a predefined target voltage for a predefined period of time. In response to determining the battery voltage remains greater than the predefined target voltage for the predefined period of time for the burn-off process, the de-passivation process can be ended. In response to determining the battery voltage does not remain greater than the predefined target voltage for the predefined period of time for the burn-off process, a further determination can be made as to whether a pre-determined maximum number of de-passivation cycles have been performed. In response to determining the pre-determined maximum number of de-passivation cycles have been performed, the de-passivation process can be ended.

In response to determining the battery voltage does not remain greater than the predefined target voltage for the predefined period of time for the burn-off process and in response to determining the pre-determined maximum number of de-passivation cycles have not yet been performed, the burn-off process on the battery 228 can be paused for a predetermined period of time. After the predetermined period of time for pausing the burn-off process on the battery 228 has expired, the performing of the burn-off process on the battery 228 and the measuring of the battery voltage during the burn-off process can be repeated until a determination is made that the battery voltage remains greater than the predefined target voltage for the predefined period of time for the burn-off process or until a determination is made that the pre-determined maximum number of de-passivation cycles have been performed.

In some cases, the battery management instructions 260 can further cause the processor 240 to provide results of at least one of the pre-check process or the de-passivation process to a remote monitoring system 104. Additionally, or alternatively, the battery management instructions 256 can further cause the processor 240 to receive updated battery management parameters 240 for at least one of the pre-check process or the de-passivation process from the remote monitoring system. The battery management parameters 248 can include, but are not limited to a target voltage for determining when to stop running the de-passivation process, a voltage hysteresis to start the de-passivation process, i.e., a difference between target voltage and measured battery voltage, a maximum amount of times a burn-off cycle is run, if target voltage is not reached, a maximum burn off cycle length, a length of sleep or pause between burn-off cycles, a length of pause between maintenance cycles, a maximum number of maintenance cycles during a battery's lifetime, etc.

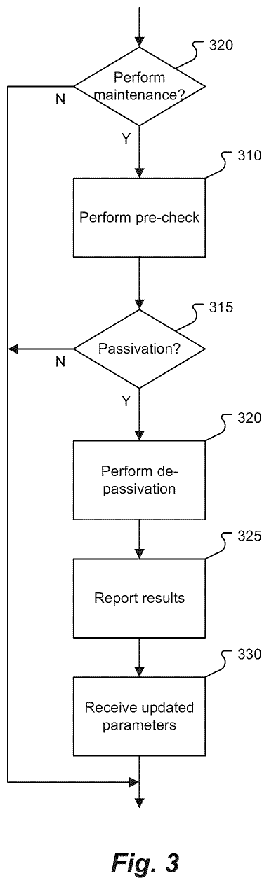

FIG. 3 is a flowchart illustrating an exemplary process for maintaining a battery of an IoT device according to one embodiment of the present disclosure. As illustrated in this example, maintaining a battery in an IoT device can comprise determining 320 whether to perform battery maintenance. Determining 320 to perform battery maintenance can comprise determining whether a predefined period of time has passed. Additionally, or alternatively, determining 320 to perform battery maintenance can comprise receiving, from a remote monitoring system, an instruction to perform battery maintenance. In response to determining 320 to perform battery maintenance, a pre-check process can be performed 310 on the battery of the IoT device. A determination 315 can be made, based on results of performing 310 the pre-check process, as to whether battery passivation is occurring on the battery of the IoT device. In response to determining 315 battery passivation is occurring on the IoT device, a de-passivation process can be performed 320 on the battery of the IoT device. In some cases, results of at least one of the pre-check process or the de-passivation process can be provided 325 to a remote monitoring system. Additionally, or alternatively, updated parameters for at least one of the pre-check process or the de-passivation process can be received 330 from the remote monitoring system.

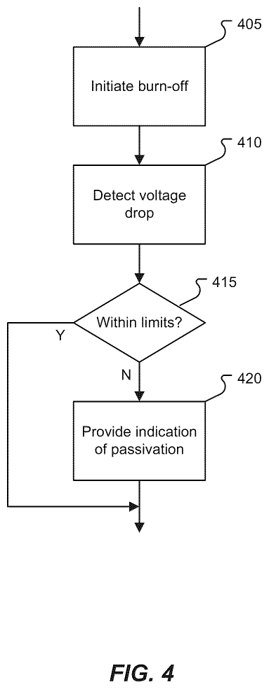

FIG. 4 is a flowchart illustrating additional details of an exemplary pre-check process according to one embodiment of the present disclosure. As illustrated in this example, performing the pre-check process on the battery of the IoT device can comprise initiating 405 a burn-off process on the battery by applying a known load to the battery for a predetermined period of time, detecting 410 a voltage drop on the battery during the burn-off process, and determining 415 whether the voltage drop on the battery during the burn-off process remains within a set of predefined limits. In response to determining 415 the voltage drop of the battery during the burn-off process does not remain within the set of predefined limits, a result indicating that battery passivation is occurring on the battery can be provided 420.

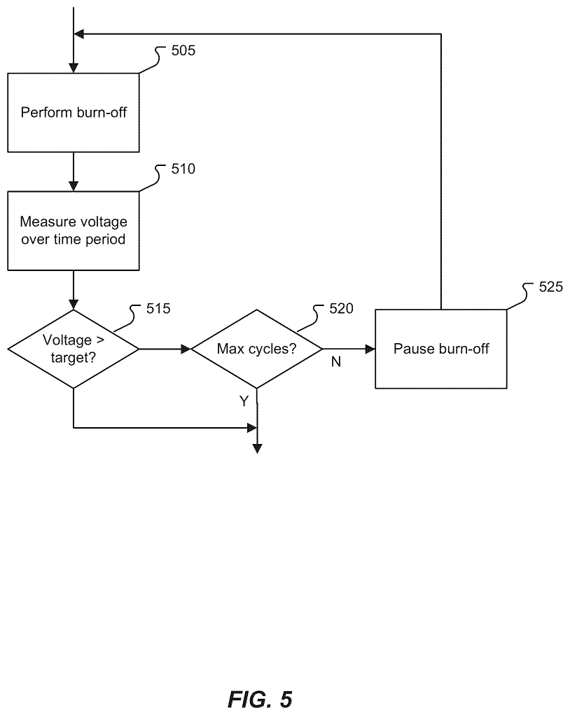

FIG. 5 is a flowchart illustrating additional details of an exemplary de-passivation process according to one embodiment of the present disclosure. As illustrated in this example, performing the de-passivation process can comprise performing 505 a burn-off process on the battery by applying a known load to the battery, measuring 510 battery voltage during the burn-off process, and determining 515 whether the battery voltage remains greater than a predefined target voltage for a predefined period of time. In response to determining 515 the battery voltage remains greater than the predefined target voltage for the predefined period of time for the burn-off process, the de-passivation process can be ended. In response to determining 515 the battery voltage does not remain greater than the predefined target voltage for the predefined period of time for the burn-off process, a further determination 520 can be made as to whether a pre-determined maximum number of de-passivation cycles have been performed. In response to determining 520 the pre-determined maximum number of de-passivation cycles have been performed, the de-passivation process can be ended.

In response to determining 515 the battery voltage does not remain greater than the predefined target voltage for the predefined period of time for the burn-off process and in response to determining 520 the pre-determined maximum number of de-passivation cycles have not yet been performed, the burn-off process on the battery can be paused 525 for a predetermined period of time. After the predetermined period of time for pausing 525 the burn-off process on the battery has expired, the performing 525 of the burn-off process on the battery and the measuring of the battery voltage during the burn-off process can be repeated until a determination 515 is made that the battery voltage remains greater than the predefined target voltage for the predefined period of time for the burn-off process or until a determination 520 is made that the pre-determined maximum number of de-passivation cycles have been performed.

The present disclosure, in various aspects, embodiments, and/or configurations, includes components, methods, processes, systems, and/or apparatus substantially as depicted and described herein, including various aspects, embodiments, configurations embodiments, sub-combinations, and/or subsets thereof. Those of skill in the art will understand how to make and use the disclosed aspects, embodiments, and/or configurations after understanding the present disclosure. The present disclosure, in various aspects, embodiments, and/or configurations, includes providing devices and processes in the absence of items not depicted and/or described herein or in various aspects, embodiments, and/or configurations hereof, including in the absence of such items as may have been used in previous devices or processes, e.g., for improving performance, achieving ease and\or reducing cost of implementation.

The foregoing discussion has been presented for purposes of illustration and description. The foregoing is not intended to limit the disclosure to the form or forms disclosed herein. In the foregoing Detailed Description for example, various features of the disclosure are grouped together in one or more aspects, embodiments, and/or configurations for the purpose of streamlining the disclosure. The features of the aspects, embodiments, and/or configurations of the disclosure may be combined in alternate aspects, embodiments, and/or configurations other than those discussed above. This method of disclosure is not to be interpreted as reflecting an intention that the claims require more features than are expressly recited in each claim. Rather, as the following claims reflect, inventive aspects lie in less than all features of a single foregoing disclosed aspect, embodiment, and/or configuration. Thus, the following claims are hereby incorporated into this Detailed Description, with each claim standing on its own as a separate preferred embodiment of the disclosure.

Moreover, though the description has included description of one or more aspects, embodiments, and/or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and/or configurations to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

What is claimed is:

1. A method for maintaining a battery in an Internet-of-Things (IoT) device, the method comprising:
determining, by a processor of the IoT device, whether to perform battery maintenance;
in response to determining to perform battery maintenance, performing, by the processor of the IoT device, a pre-check process on the battery of the IoT device;
determining, by the processor of the IoT device, based on results of performing the pre-check process, whether battery passivation is occurring on the battery of the IoT device; and
in response to determining battery passivation is occurring on the IoT device, performing, by the processor of the IoT device, a de-passivation process on the battery of the IoT device.

2. The method of claim 1, further comprising providing, by the processor of the IoT device, to a remote monitoring system, results of at least one of the pre-check process or the de-passivation process.

3. The method of claim 2, further comprising receiving, by the processor of the IoT device, from the remote monitoring system, updated parameters for at least one of the pre-check process or the de-passivation process.

4. The method of claim 1, wherein determining to perform battery maintenance comprises determining whether a predefined period of time has passed.

5. The method of claim 1, wherein determining to perform battery maintenance comprises receiving, from a remote monitoring system, an instruction to perform battery maintenance.

6. The method of claim 1, wherein performing the pre-check process on the battery of the IoT device comprises:
initiating a burn-off process on the battery by applying a known load to the battery for a predetermined period of time;
detecting a voltage drop on the battery during the burn-off process;
determining whether the voltage drop on the battery during the burn-off process remains within a set of predefined limits; and
in response to determining the voltage drop of the battery during the burn-off process does not remain within the set of predefined limits, providing a result indicating that battery passivation is occurring on the battery.

7. The method of claim 1, wherein performing the de-passivation process comprises:
performing a burn-off process on the battery by applying a known load to the battery;
measuring battery voltage during the burn-off process;
determining whether the battery voltage remains greater than a predefined target voltage for a predefined period of time; and
in response to determining the battery voltage remains greater than the predefined target voltage for the predefined period of time for the burn-off process, ending the de-passivation process.

8. The method of claim 7, wherein performing the de-passivation process further comprises:
in response to determining the battery voltage does not remain greater than the predefined target voltage for the predefined period of time for the burn-off process, further determining whether a pre-determined maximum number of de-passivation cycles have been performed; and
in response to determining the pre-determined maximum number of de-passivation cycles have been performed, ending the de-passivation process.

9. The method of claim 8, wherein performing the de-passivation process further comprises:
in response to determining the pre-determined maximum number of de-passivation cycles have not yet been performed, pausing the burn-off process on the battery for a predetermined period of time.

10. The method of claim 9, wherein performing the de-passivation process further comprises, after the predetermined period of time for pausing the burn-off process on the battery has expired, repeating the performing of the burn-off process on the battery and the measuring of the battery voltage during the burn-off process until determining the battery voltage remains greater than the predefined target voltage for the predefined period of time for the burn-off process or until determining the pre-determined maximum number of de-passivation cycles have been performed.

11. An Internet-of-Things (IoT) device comprising:
a processor; and
a memory coupled with and readable by the processor and storing therein a set of instructions which, when executed by the processor, causes the processor to:
determining whether to perform battery maintenance;
in response to determining to perform battery maintenance, performing a pre-check process on the battery of the IoT device;
determining based on results of performing the pre-check process, whether battery passivation is occurring on the battery of the IoT device; and
in response to determining battery passivation is occurring on the IoT device, performing a de-passivation process on the battery of the IoT device.

12. The IoT device of claim 11, further comprising providing, to a remote monitoring system, results of at least one of the pre-check process or the de-passivation process.

13. The IoT device of claim 12, further comprising receiving, from the remote monitoring system, updated parameters for at least one of the pre-check process or the de-passivation process.

14. The IoT device of claim 11, wherein determining to perform battery maintenance comprises determining whether a predefined period of time has passed.

15. The IoT device of claim 11, wherein determining to perform battery maintenance comprises receiving, from a remote monitoring system, an instruction to perform battery maintenance.

16. The IoT device of claim 11, wherein performing the pre-check process on the battery of the IoT device comprises:
initiating a burn-off process on the battery by applying a known load to the battery for a predetermined period of time;
detecting a voltage drop on the battery during the burn-off process;
determining whether the voltage drop on the battery during the burn-off process remains within a set of predefined limits; and
in response to determining the voltage drop of the battery during the burn-off process does not remain within the set of predefined limits, providing a result indicating that battery passivation is occurring on the battery.

17. The IoT device of claim 11, wherein performing the de-passivation process comprises:
performing a burn-off process on the battery by applying a known load to the battery;
measuring battery voltage during the burn-off process;
determining whether the battery voltage remains greater than a predefined target voltage for a predefined period of time; and
in response to determining the battery voltage remains greater than the predefined target voltage for the predefined period of time for the burn-off process, ending the de-passivation process.

18. The IoT device of claim 17, wherein performing the de-passivation process further comprises:
in response to determining the battery voltage does not remain greater than the predefined target voltage for the predefined period of time for the burn-off process, further determining whether a pre-determined maximum number of de-passivation cycles have been performed; and
in response to determining the pre-determined maximum number of de-passivation cycles have been performed, ending the de-passivation process.

19. The IoT device of claim 18, wherein performing the de-passivation process further comprises:
in response to determining the pre-determined maximum number of de-passivation cycles have not yet been performed, pausing the burn-off process on the battery for a predetermined period of time.

20. The IoT device of claim 19, wherein performing the de-passivation process further comprises, after the predetermined period of time for pausing the burn-off process on the battery has expired, repeating the performing of the burn-off process on the battery and the measuring of the battery voltage during the burn-off process until determining the battery voltage remains greater than the predefined target voltage for the predefined period of time for the burn-off process or until determining the pre-determined maximum number of de-passivation cycles have been performed.
